(19) United States
(12) Patent Application Publication
(10) Pub. No.: US 2008/0296051 A1
(43) Pub. Date: Dec. 4, 2008

(54) PRINTED CIRCUIT BOARD

(75) Inventor: Kouichi YAMAGUCHI, Osaka (JP)

Correspondence Address: PANITCH SCHWARZE BELISARIO & NADEL LLP, ONE COMMERCE SQUARE, 2005 MARKET STREET, SUITE 2200, PHILADELPHIA, PA, 19103, US

(73) Assignee: NITTO DENKO CORPORATION, Osaka (JP)

(21) Appl. No.: 12/127,364

(22) Filed: May 27, 2008

(30) Foreign Application Priority Data
May 28, 2007 (JP) 2007-140400

(51) Int. Cl. H05K 1/09

(52) U.S. Cl. 174/257

(57) ABSTRACT

A printed circuit board includes a base insulating layer and a wiring. The wiring is composed of a terminal portion on an upper surface side of the base insulating layer, a copper plating layer inside a through hole of the base insulating layer and a wiring pattern on a lower surface side of the base insulating layer. A protective plating layer is provided on the upper surface side of the base insulating layer so as to cover the terminal portion and the copper plating layer inside the through hole. A cover insulating layer is provided on the lower surface side of the base insulating layer so as to cover the wiring pattern.

### BACKGROUND OF THE INVENTION

1. Field of the Invention

The present invention relates to a printed circuit board used for various types of electric equipment and electronic equipment.

2. Description of the Background Art

Printed circuit boards (see JP 5-152692 A, for example) are used for various types of electric equipment or electronic equipment.

Generally, a wiring pattern made of copper is formed on a base insulating layer in the printed circuit board. Although a cover insulating layer is normally formed on the wiring pattern, a terminal portion of the wiring pattern is exposed. When such a printed circuit board is used under a high-temperature and high-humidity condition for a long time, copper ions may be eluted in the terminal portion that is exposed. In this case, the copper ions are liable to cause the adjacent wiring patterns to be short-circuited.

Conventionally, a technique for covering the terminal portion of the wiring pattern with a gold plating layer has been used to prevent the foregoing ion-migration of copper.

FIG. 13 is a diagram showing the conventional printed circuit board. Note that in FIG. 13, (a) is a perspective view showing the appearance of one end of the printed circuit board, and (b) is a sectional view of the printed circuit board.

In the printed circuit board 500 shown in FIG. 13, a plurality of wiring patterns 502 are formed on a base insulating layer 501. A cover insulating layer 503 is formed on the base insulating layer 501 so as to cover surfaces of the wiring patterns 502, excluding terminal portions of the wiring patterns 502. In addition, nickel plating layers 504 and gold plating layers 505 are formed on surfaces of the terminal portions of the wiring patterns 502 that are not covered with the cover insulating layer 503.

In this printed circuit board 500, the surfaces of the terminal portions of the wiring patterns 502 are covered with the nickel plating layers 504 and the gold plating layers 505. This prevents occurrence of ion migration of copper in the terminal portions of the wiring patterns 502.

In the configuration of the printed circuit board 500 of FIG. 13, however, copper ions may be eluted at a boundary between the cover insulating layer 503 and the nickel plating layer 504 and a boundary between the cover insulating layer 503 and the gold plating layer 505. This causes short-circuits between the wiring patterns 502 in some cases.

### SUMMARY OF THE INVENTION

An object of the present invention is to provide a printed circuit board in which electrical short circuits caused by ion migration are prevented.

(1) According to an aspect of the present invention, a printed circuit board includes a base insulating layer including a first through hole, a terminal portion that is made of a metal material and provided on a region, including the first through hole, of one surface of the base insulating layer, a first conductor pattern provided on a region, including the first through hole, of the other surface of the base insulating layer, a first metal layer that electrically connects the terminal portion and the first conductor pattern through the first through hole, a protective layer that is made of a metal material and provided on the side of the one surface of the base insulating layer so as to cover the terminal portion and the first metal layer, and a first insulating cover layer that is provided on the other surface of the base insulating layer so as to cover the first conductor pattern and the first through hole.

In this printed circuit board, the terminal portion made of the metal material is provided on the one surface of the base insulating layer, and the first conductor pattern is provided on the other surface of the base insulating layer. The terminal portion and the first conductor pattern are electrically connected to each other through the first through hole by the first metal layer. In addition, the protective layer made of the metal material is provided on the side of the one surface of the base insulating layer so as to cover the terminal portion and the first through hole, and the first insulating cover layer is provided on the side of the other surface of the base insulating layer so as to cover the first conductor pattern and the first through hole. Thus, an electronic component can be connected to the terminal portion in this printed circuit board.

Here, the first conductor pattern and the first through hole are covered with the first cover insulating layer on the side of the other surface of the base insulating layer. This prevents ion migration from the first conductor pattern and the first metal layer inside the first through hole. Moreover, since the terminal portion is covered with the protective layer, ion migration from the terminal portion can be prevented. Furthermore, the boundary between the first insulating cover layer and the protective layer is inside the first through hole. Therefore, even when metal ions are eluted from the terminal portion or the first metal layer, the metal ions can be prevented from reaching other terminal portion or conductor pattern through the boundary between the first insulating cover layer and the protective layer.

As a result of these, electrical short-circuits caused by ion migration can be prevented even when the printed circuit board is used under a high temperature and high humidity condition.

(2) The metal material for the protective layer may include at least one of nickel, gold and solder. In this case, ion migration from the terminal portion can be reliably prevented.

(3) The first metal layer may be provided along an inner wall surface of the first through hole, and the protective layer may be provided in the first through hole so as to cover a surface of the first metal layer.

In this case, the first metal layer and the protective layer can be formed by plating. This allows the printed circuit board to be easily manufactured.

(4) The base insulating layer may further include a second through hole, the first conductor pattern may be provided on a region, including the first and second through holes, of the other surface of the base insulating layer, and the printed circuit board may further include a second conductor pattern provided on a region, including the second through hole, of the one surface of the base insulating layer, a second metal layer that connects the first conductor pattern and the second conductor pattern through the second through hole, and a second insulating cover layer provided on the one surface of the base insulating layer so as to cover the second conductor pattern and the second through hole.

In this printed circuit board, the second insulating cover layer is provided on the one surface of the base insulating layer so as to cover the second conductor pattern and the second through hole. This prevents ion migration from the second conductor pattern and the second metal layer inside the second through hole.

Other features, elements, characteristics, and advantages of the present invention will become more apparent from the following description of preferred embodiments of the present invention with reference to the attached drawings.

### BRIEF DESCRIPTION OF THE DRAWINGS

FIG. 1 is a schematic diagram explaining a step of manufacturing a printed circuit board according to a first embodiment;

FIG. 2 is a schematic diagram explaining a step of manufacturing the printed circuit board according to the first embodiment;

FIG. 3 is a schematic diagram explaining a step of manufacturing the printed circuit board according to the first embodiment;

FIG. 4 is a schematic diagram explaining a step of manufacturing the printed circuit board according to the first embodiment;

FIG. 5 is a schematic diagram explaining a step of manufacturing the printed circuit board according to the first embodiment;

FIG. 6 is a schematic diagram explaining a step of manufacturing the printed circuit board according to the first embodiment;

FIG. 7 is a schematic diagram explaining a step of manufacturing a printed circuit board according to a second embodiment;

FIG. 8 is a schematic diagram explaining a step of manufacturing the printed circuit board according to the second embodiment;

FIG. 9 is a schematic diagram explaining a step of manufacturing the printed circuit board according to the second embodiment;

FIG. 10 is a schematic diagram explaining a step of manufacturing the printed circuit board according to the second embodiment;

FIG. 11 is a schematic diagram explaining a step of manufacturing the printed circuit board according to the second embodiment;

FIG. 12 is a diagram showing a printed circuit board of a comparative example; and

FIG. 13 is a diagram showing a conventional printed circuit board.

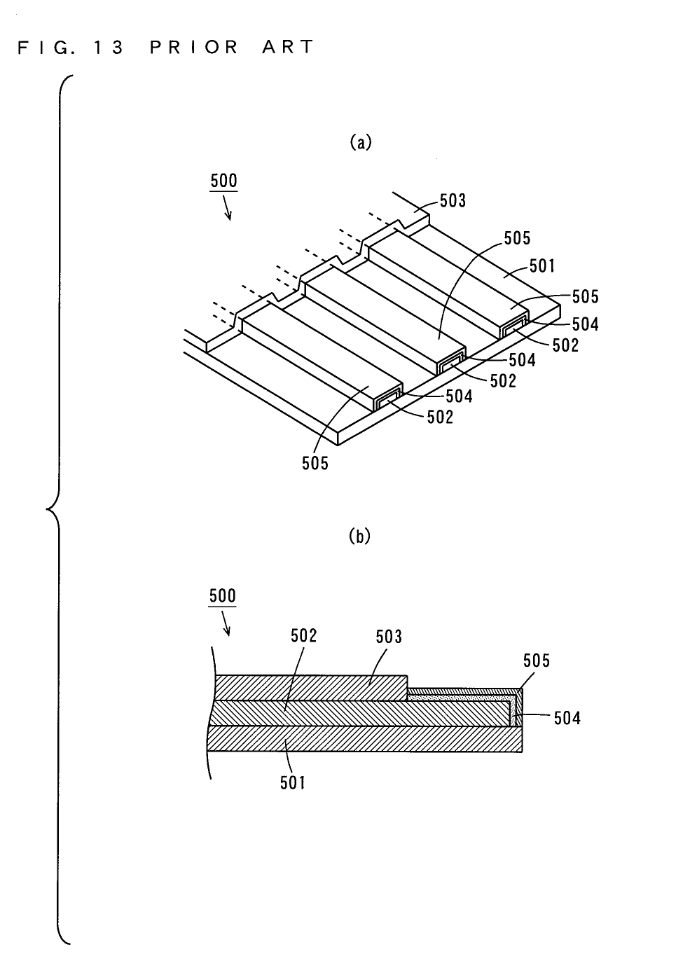

### DESCRIPTION OF THE PREFERRED EMBODIMENTS

Hereinafter, flexible printed circuit boards (hereinafter abbreviated as printed circuit boards) according to embodiments of the present invention are described while referring to drawings.

### First Embodiment

(1) Manufacturing Method of the Printed Circuit Board

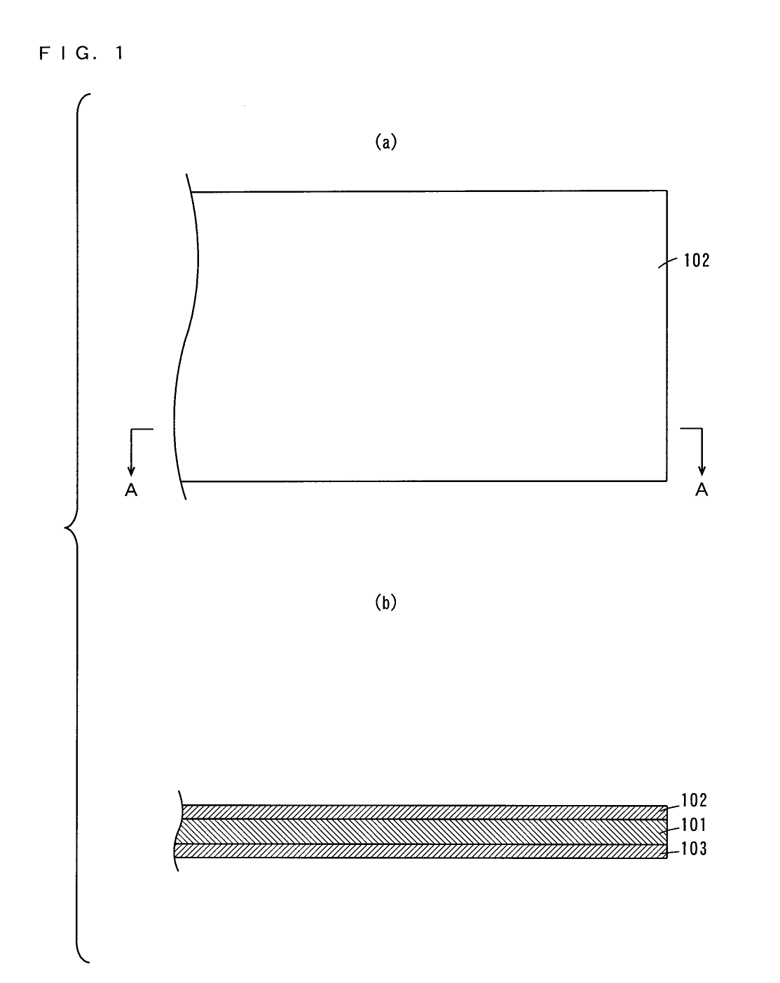

FIGS. 1 to 6 are schematic diagrams explaining steps of manufacturing the printed circuit board according to a first embodiment of the present invention. Note that (a) is a top view, and (b) is a sectional view taken along the line A-A of (a) in each of FIGS. 1 to 6. FIGS. 1 to 6 show one end of the printed circuit board.

First, as shown in FIG. 1, a substrate with which metal foils 102, 103 made of copper are provided at both surfaces of a long-sized base insulating layer 101 made of polyimide is prepared. Note that examples of the material for the base insulating layer 101 may include other materials such as polyethylene terephthalate, polyethernitrile and polyether sulfone. In addition, another metal foil such as an aluminum foil or a nichrome foil may be used as the metal foils 102, 103.

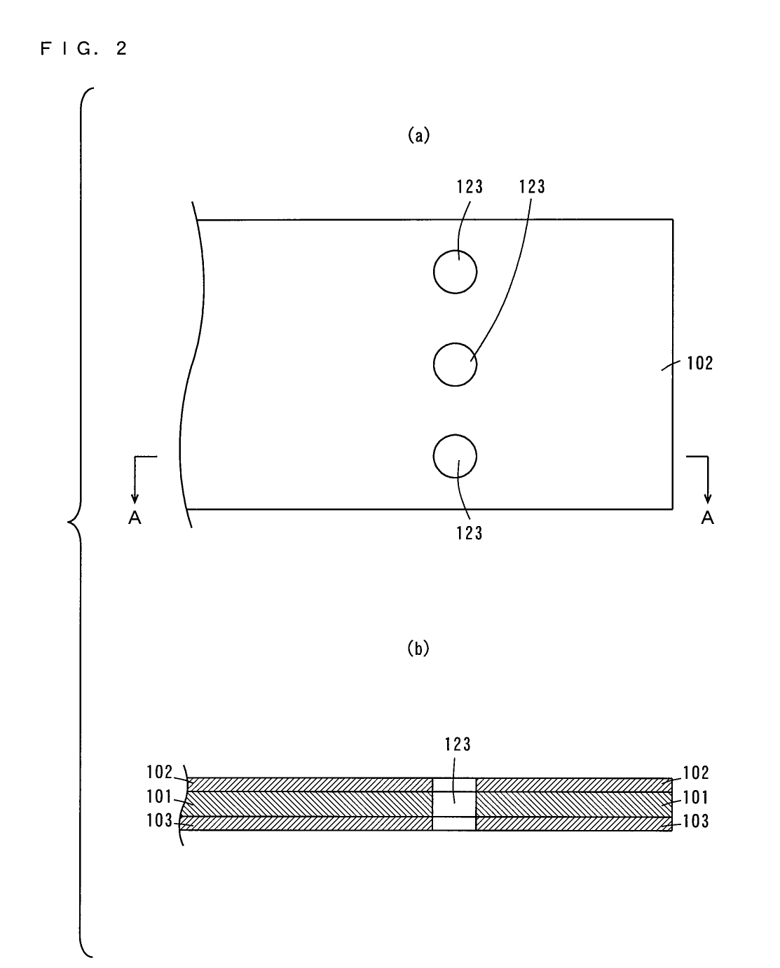

Next, a plurality of (three in the present embodiment) through holes 123 are formed by lasering so as to penetrate the metal foil 102, the base insulating layer 101 and the metal foil 103 as shown in FIG. 2.

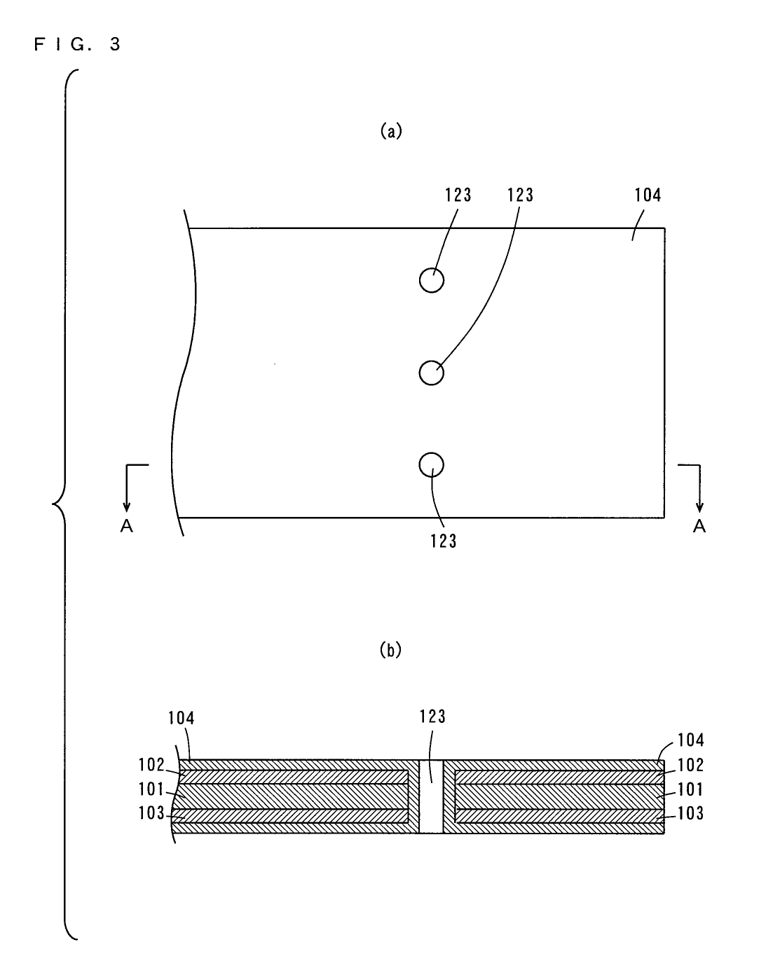

A copper plating layer 104 is subsequently formed so as to cover inner wall surfaces of the through holes 123, an upper surface of the metal foil 102 and a lower surface of the metal foil 103 as shown in FIG. 3. Note that, for example, an electroless copper plating layer having a thickness of 0.2 μm is formed so as to cover the inner wall surfaces of the through holes 123, the upper surface of the metal foil 102 and the lower surface of the metal foil 103, and an electrolytic copper plating layer having a thickness of 10 μm is subsequently formed on the electroless copper plating layer, thereby forming the copper plating layer 104.

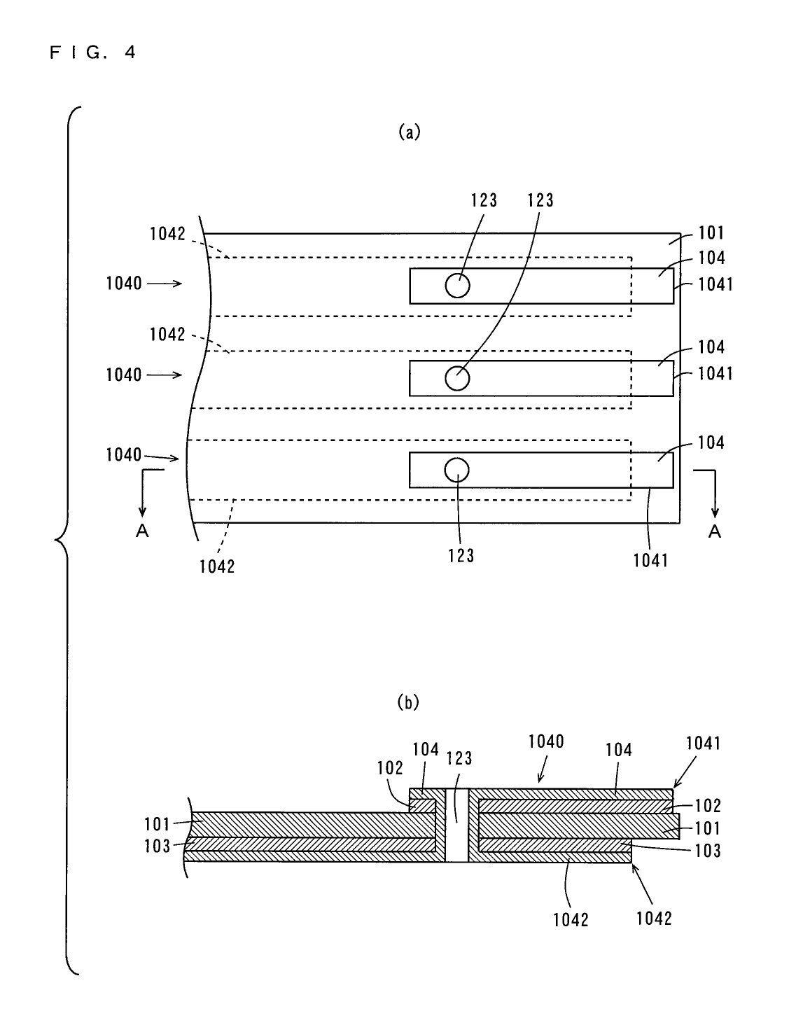

Then, the metal foil 102 and the copper plating layer 104 are removed by etching on the upper surface side of the base insulating layer 101, excluding a plurality of long-sized regions each including the through hole 123 as shown in FIG. 4. Thus, a plurality of long-sized terminal portions 1041 composed of the metal foils 102 and the copper plating layers 104 are formed on the upper surface of the base insulating layer 101.

In addition, the metal foil 103 and the copper plating layer 104 are removed by etching on the lower surface side of the base insulating layer 101, excluding a plurality of long-sized regions each including the through hole 123. Thus, a plurality of long-sized wiring patterns 1042 composed of the metal foil 103 and the copper plating layer 104 are formed on the lower surface of the base insulating layer 101.

As a result of these, a plurality of wirings 1040 composed of the terminal portions 1041, the copper plating layers 104 inside the through holes 123 and the wiring patterns 1042 are formed. Note that the width of each of the wiring patterns 1042 is set larger than the width of each of the terminal portions 1041 in the present embodiment. In addition, one ends of the terminal portions 1041 and one end of the base insulating layer 101 are positioned so as to be misaligned with one another, and one ends of the wiring patterns 1042 and the one end of the base insulating layer 101 are positioned so as to be misaligned with one another.

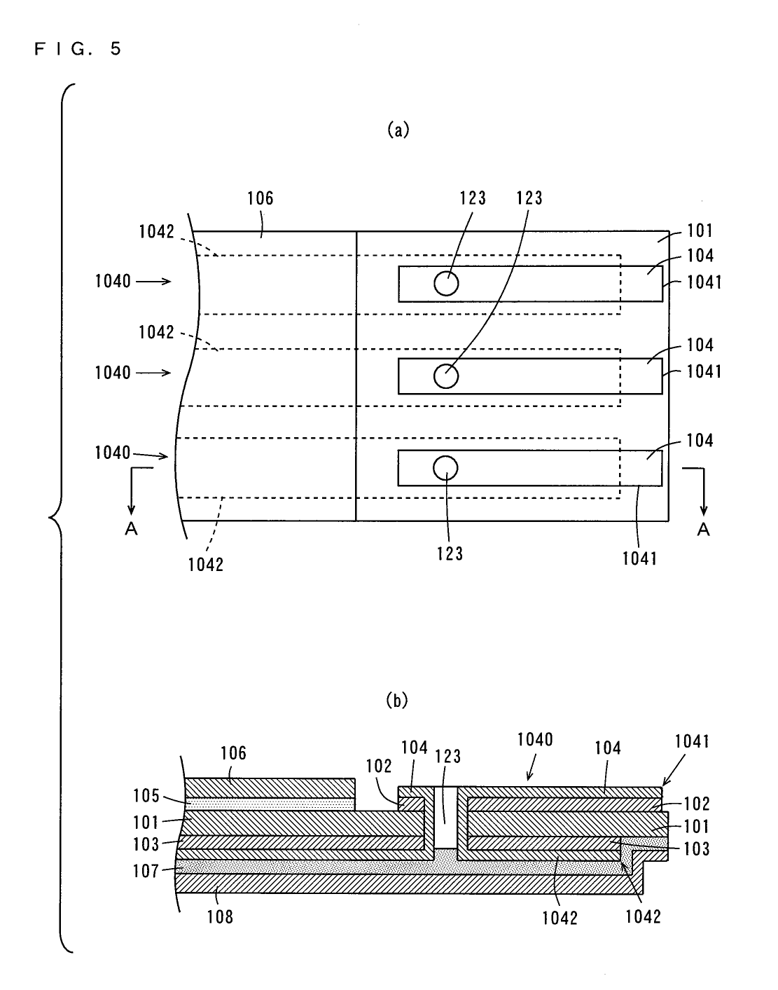

Next, as shown in FIG. 5, a cover insulating layer 106 is provided on the upper surface of the base insulating layer 101 with an adhesive layer 105 sandwiched therebetween such that the terminal portions 1041 are exposed. In addition, a cover insulating layer 108 is provided on the lower surface of the base insulating layer 101 with an adhesive layer 107 sandwiched therebetween so as to cover the wiring patterns 1042.

Examples of the materials for the adhesive layers 105, 107 include acrylic adhesives, epoxy adhesives, polyimide adhesives and the like. In addition, examples of the materials for the cover insulating layers 106, 108 include polyimide, polyethylene terephthalate, polyethernitrile, polyethersulfone and the like.

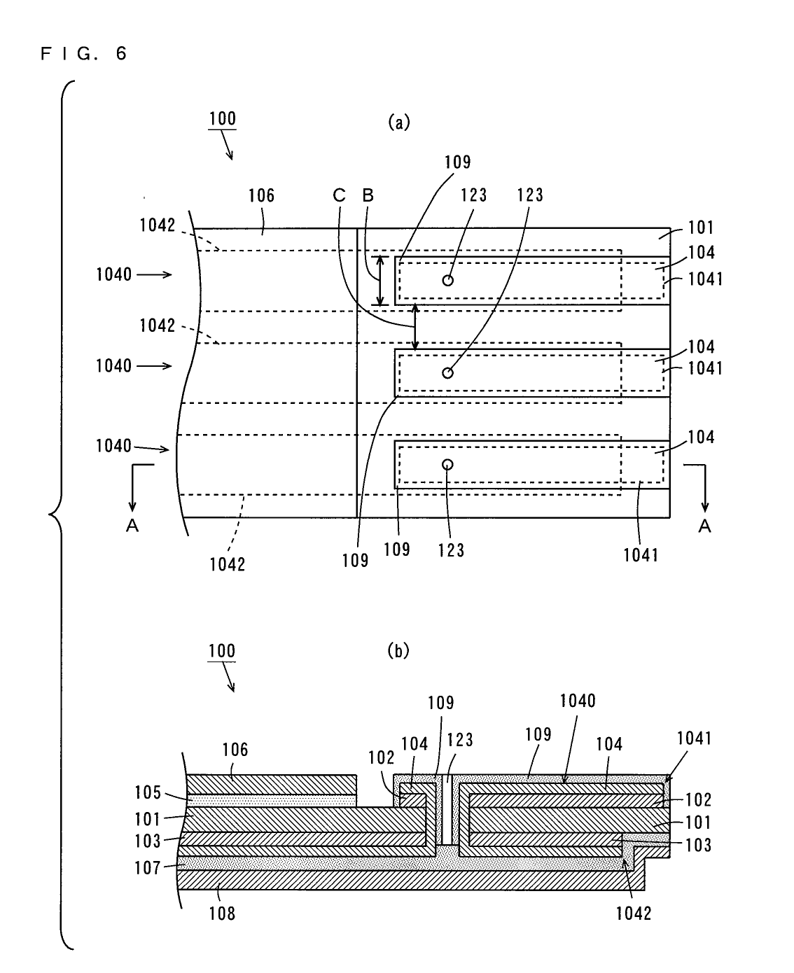

Next, protective plating layers 109 are formed so as to cover surfaces of the terminal portions 1041 and surfaces of the copper plating layers 104 inside the through holes 123 as shown in FIG. 6. Accordingly, a printed circuit board 100 is completed. Note that the protective plating layers 109 are each composed of a nickel plating layer and a gold plating layer that is laminated on the nickel plating layer.

In the printed circuit board 100 according to the present embodiment, terminals of electronic components are connected to the terminal portions 1041 (the protective plating layers 109). When connectors of the electronic components are engaged with the one end of the printed circuit board 100, it is desirable that the through holes 123 are formed at such positions that tips of connecting pins of the connectors do not reach.

### (2) Effects of the Present Embodiment

As described above, since the terminal portions 1041 are covered with the protective plating layers 109, ion migration from the terminal portions 1041 can be prevented in the printed circuit board 100 according to the present embodiment. In addition, since the wiring patterns 1042 are covered with the cover insulating layer 108, ion migration from the wiring patterns 1042 can be prevented.

Furthermore, boundaries between the protective plating layers 109 and the cover insulating layer 108 are inside the through holes 123. Therefore, even when copper ions are eluted from the terminal portions 1041 or the wiring patterns 1042, the copper ions can be prevented from reaching other terminal portions 1041 or wiring patterns 1042 through the boundaries between the protective plating layers 109 and the cover insulating layer 108.

As a result of these, occurrence of electrical short-circuits caused by ion migration can be prevented even when the printed circuit board 100 is used under a high temperature and high humidity condition.

### Second Embodiment

### (1) Manufacturing Method of the Printed Circuit Board

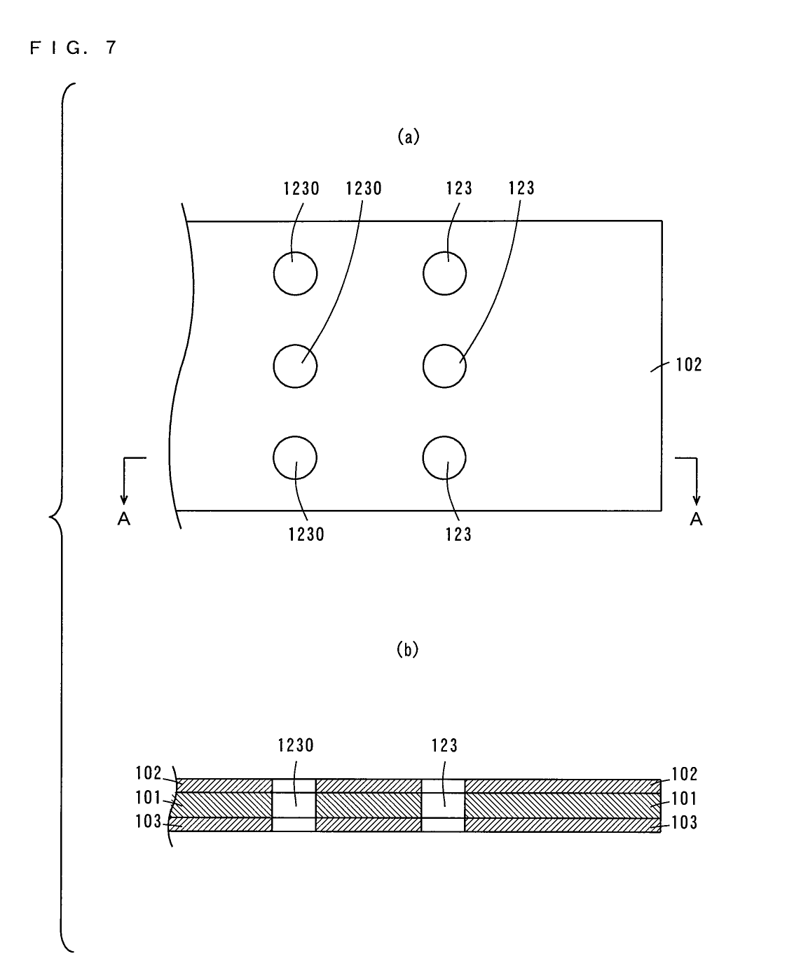

FIGS. 7 to 11 are schematic diagrams explaining steps of manufacturing the printed circuit board according to a second embodiment of the present invention. Note that (a) is a top view, and (b) is a sectional view taken along the line A-A of (a) in each of FIGS. 7 to 11. FIGS. 7 to 11 show one end of the printed circuit board.

First, similarly to the substrate of FIG. 1, a substrate with which the metal foils 102, 103 are provided at the both sides of the base insulating layer 101 is prepared.

Next, a plurality of pairs of (three pairs in the present embodiment) through holes 123 and through holes 1230 are formed by lasering as shown in FIG. 7. Note that each pair of through holes 123, 1230 are formed so as to be positioned in the same straight line along a longitudinal direction of the base insulating layer 101 in the present embodiment.

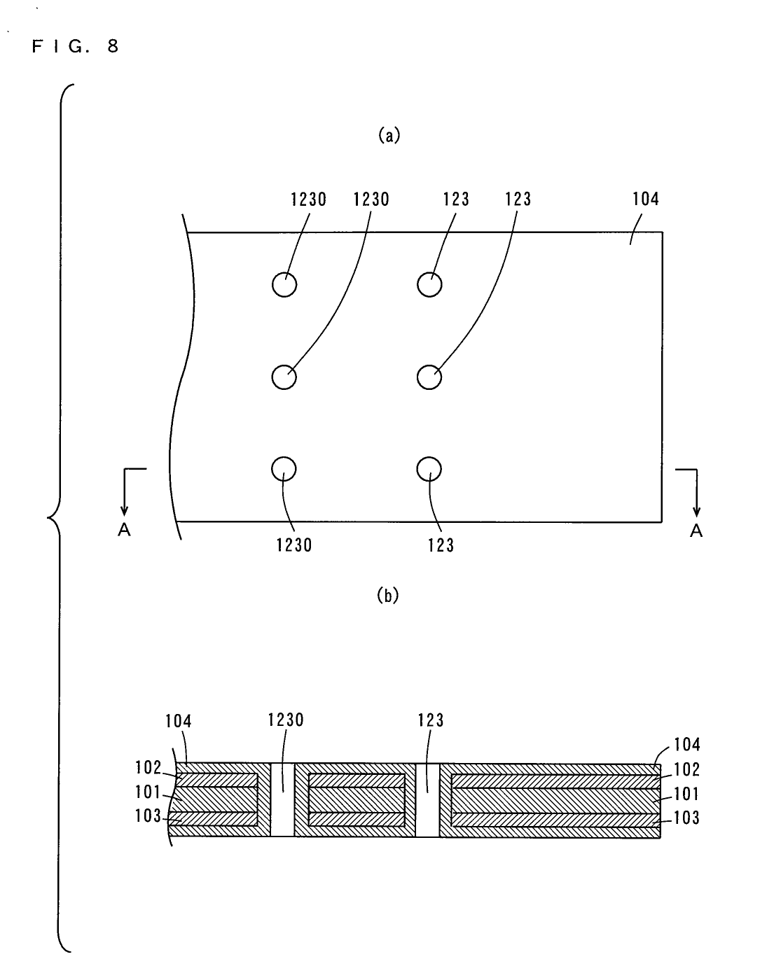

The copper plating layer 104, which is the same as that in FIG. 3, is subsequently formed so as to cover inner wall surfaces of the through holes 123, 1230, the upper surface of the metal foil 102 and the lower surface of the metal foil 103 as shown in FIG. 8.

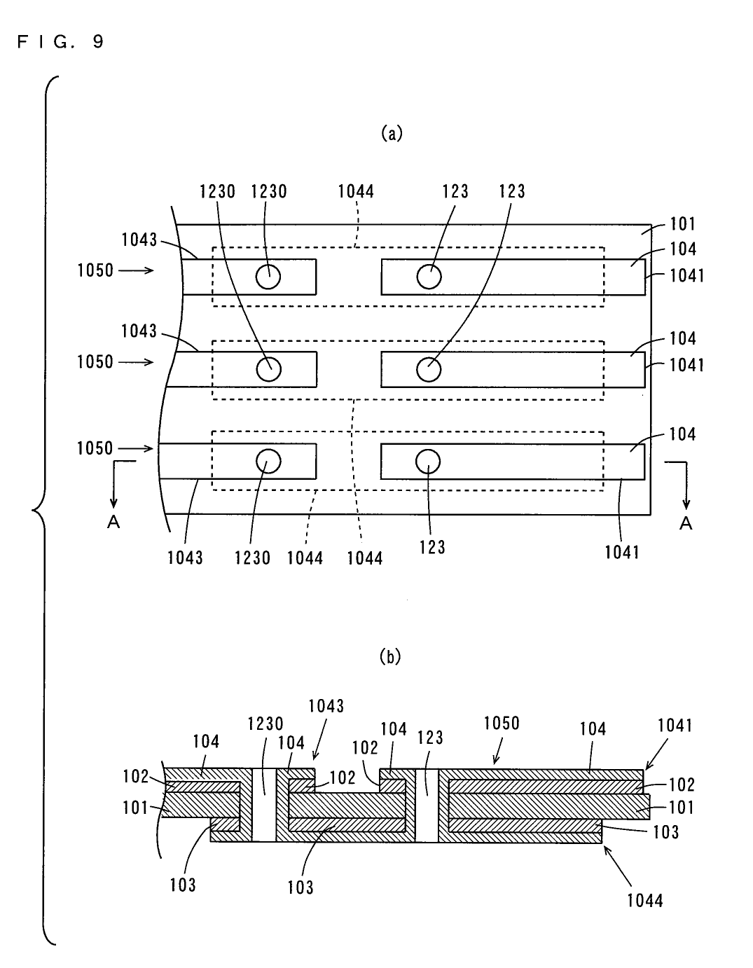

Then, the metal foil 102 and the copper plating layer 104 are removed by etching on the upper surface side of the base insulating layer 101, excluding a plurality of long-sized regions each including the through hole 123 and a plurality of long-sized regions each including the through hole 1230 as shown in FIG. 9. Accordingly, the plurality of terminal portions 1041 that are the same as those in FIG. 4 and a plurality of long-sized wiring patterns 1043 composed of the metal foils 102 and the copper plating layers 104 are formed on the upper surface of the base insulating layer 101.

In addition, the metal foil 103 and the copper plating layer 104 are removed by etching on the lower surface side of the base insulating layer 101, excluding a plurality of long-sized regions each including the pair of through holes 123, 1230. Thus, a plurality of long-sized wiring patterns 1044 composed of the metal foils 103 and the copper plating layers 104 are formed on the lower surface of the base insulating layer 101.

As a result of these, a plurality of wirings 1050 composed of the terminal portions 1041, the copper plating layers 104 inside the through holes 123, the wiring patterns 1044, the copper plating layers 104 inside the through holes 1230 and the wiring patterns 1043 is formed. Note that the width of each of the wiring patterns 1044 is set larger than the width of each of the terminal portions 1041 and the width of each of the wiring patterns 1043 in the present embodiment. In addition, the one ends of the terminal portions 1041 and the one end of the base insulating layer 101 are positioned so as to be misaligned with each other, and one ends of the wiring patterns 1044 and the one end of the base insulating layer 101 are positioned so as to be misaligned with each other.

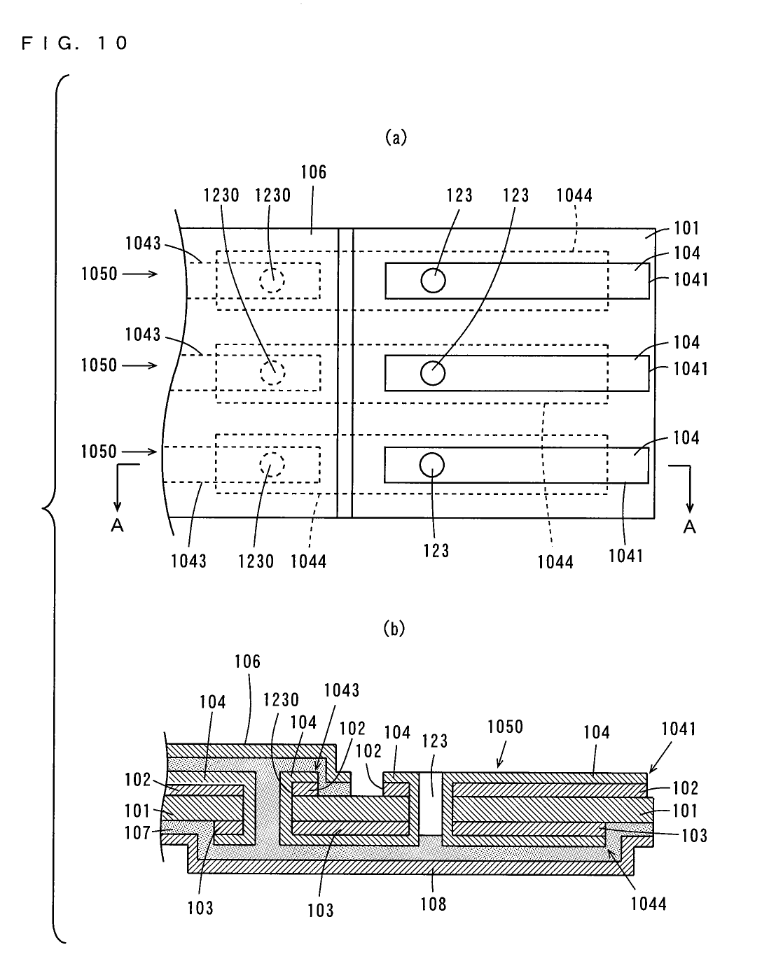

Next, the cover insulating layer 106 is provided on the upper surface of the base insulating layer 101 with the adhesive layer 107 sandwiched therebetween such that the terminal portions 1041 are exposed as shown in FIG. 10. Moreover, the cover insulating layer 108 is provided on the lower surface of the base insulating layer 101 with the adhesive layer 107 sandwiched therebetween so as to cover the wiring patterns 1044.

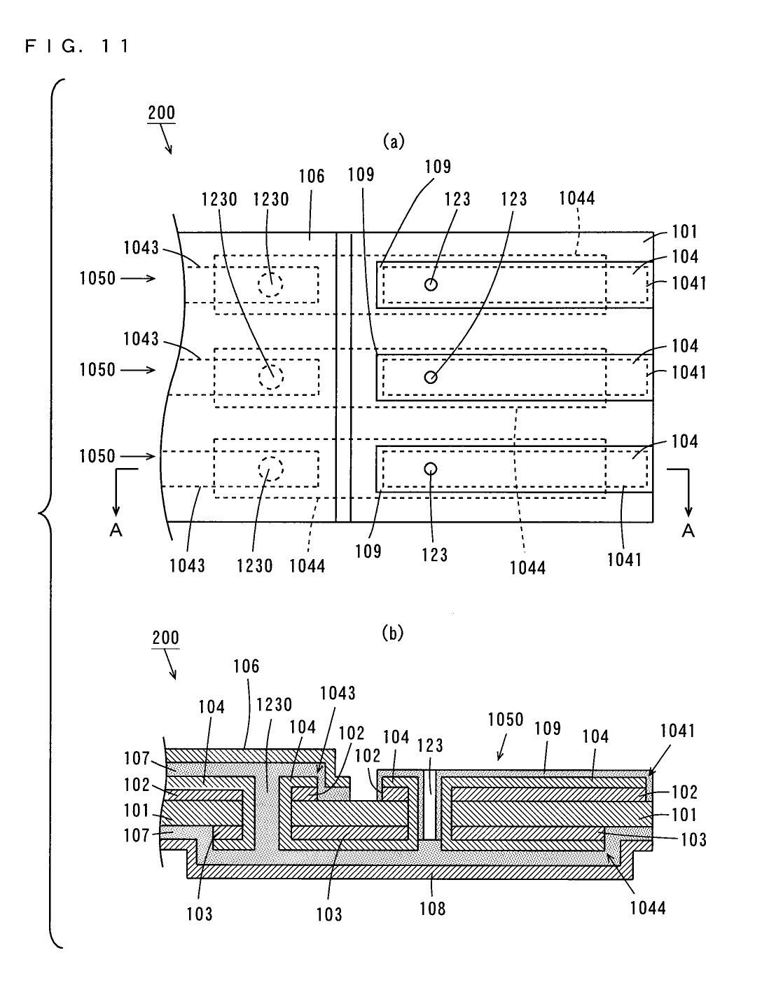

Then, the protective plating layers 109 are formed so as to cover the surfaces of the terminal portions 1041 and the surfaces of the copper plating layers 104 inside the through holes 123 as shown in FIG. 11. Accordingly, a printed circuit board 200 is completed.

### (2) Effects of the Present Embodiment

As described above, the wiring patterns 1043 on the upper surface side of the base insulating layer 101 and the wiring patterns 1044 on the lower surface side are electrically connected to one another by the copper plating layers 104 inside the through holes 1230 in the printed circuit board 200 according to the present embodiment. That is, the wirings 1050 composed of the wiring patterns 1043, 1044 can be freely disposed in arbitrary patterns on the upper surface and the lower surface of the base insulating layer 101 by using the through holes 1230 in the present embodiment. This provides improved design flexibility of the printed circuit board 200.

In addition, since the terminal portions 1041 are covered with the protective plating layers 109, ion migration from the terminal portions 1041 can be prevented. Moreover, since the wiring patterns 1043 are covered with the cover insulating layer 106 and the wiring patterns 1044 are covered with the cover insulating layer 108, ion migration from the wiring patterns 1043, 1044 can be prevented.

Furthermore, the boundaries between the protective plating layers 109 and the cover insulating layer 108 are inside the through holes 123. Therefore, even when copper ions are eluted from the terminal portions 1041 or the wiring patterns 1044, the copper ions can be prevented from reaching other terminal portions 1041 or wiring patterns 1043, 1044 through the boundaries between the protective plating layers 109 and the cover insulating layer 108.

As a result of these, occurrence of electrical short-circuits caused by ion migration can be prevented even when the printed circuit board 200 is used under the high temperature and high humidity condition.

### (3) Other Embodiments

Although the protective plating layer 109 composed of the nickel plating layer and the gold plating layer is taken as an example in the above-described embodiments, the structure of the protective plating layer 109 is not limited to the example described above. For example, the protective plating layer 109 may be a single layer of the nickel plating layer or a single layer of the gold plating layer. Another metal plating layer such as a solder plating layer may be provided instead of the nickel plating layer or the gold plating layer.

While the three wirings 1040, 1050 are formed in the above-described embodiment, two wirings 1040, 1050 or four or more wirings 1040, 1050 may be formed.

While the copper plating layers 104 are formed along the inner wall surfaces of the through holes 123 in the above-described embodiments, the copper plating layers 104 may be formed so as to be filled in the through holes 123. Note that in this case, the protective plating layers 109 are formed so as to cover the terminal portions 1041 and the copper plating layers 104 that are filled in the through holes 123.

Plating layers including a metal other than copper may be formed in the through holes 123, 1230. For example, plating layers made of copper alloy may be formed in the through holes 123, 1230.

While the wirings 1040, 1050 are formed by a subtractive method in the above-described embodiments, the wirings 1040, 1050 may be formed by an additive method or a semi-additive method.

### (4) Correspondences Between Elements in the Claims and Parts in Embodiments

In the following paragraph, non-limiting examples of correspondences between various elements recited in the claims below and those described above with respect to various embodiments of the present invention are explained.

In the above-described embodiments, the through hole 123 is an example of a first through hole, the wiring pattern 1042 or the wiring pattern 1044 is an example of a first conductor pattern, the copper plating layer 104 is an example of a first metal layer or a second metal layer, the protective plating layer 109 is an example of a protective layer, the cover insulating layer 108 is an example of a first insulating cover layer, the through hole 1230 is an example of a second through hole, the wiring pattern 1043 is an example of a second conductor pattern, and a cover insulating layer 106 is an example of a second insulating cover layer.

As each of various elements recited in the claims, various other elements having configurations or functions described in the claims can be also used.

While preferred embodiments of the present invention have been described above, it is to be understood that variations and modifications will be apparent to those skilled in the art without departing the scope and spirit of the present invention. The scope of the present invention, therefore, is to be determined solely by the following claims.

### EXAMPLES

Printed circuit boards of inventive examples and a comparative example were manufactured, and then tested for their reliability.

### (1) Inventive Example 1

In the inventive example 1, the printed circuit board 100 having the configuration described in FIGS. 1 to 6 was manufactured. In the printed circuit board 100 of the inventive example 1, the base insulating layer 101 was made of polyimide having a thickness of 25 μm, and copper foils having a thickness of 10 μm were used as the metal foils 102, 103. The diameter of each through hole 123 was set at 70 μm.

The electroless copper plating layers having the thickness of 0.2 μm were formed so as to cover the inner wall surfaces of the through holes 123, the upper surface of the metal foil 102 and the lower surface of the metal foil 103, and then the electrolytic plating layers having the thickness of 10 μm were formed on the electroless copper plating layers, thereby forming the copper plating layers 104. Polyimide films with adhesives were used as the adhesive layer 105 and the cover insulating layer 106.

Each protective plating layer 109 was composed of the electrolytic nickel plating layer having a thickness of 6 μm and the electrolytic gold plating layer having a thickness of 0.3 μm. Note that the width B (see FIG. 6) of each of the protective plating layers 109 on the terminal portion 1041 was 150 μm, and the interval C (see FIG. 6) between the adjacent protective plating layers 109 was 50 μm.

### (2) Inventive Example 2

In an inventive example 2, the printed circuit board 200 described in FIGS. 7 to 11 was manufactured in the same condition as that of the inventive example 1.

### (3) Comparative Example

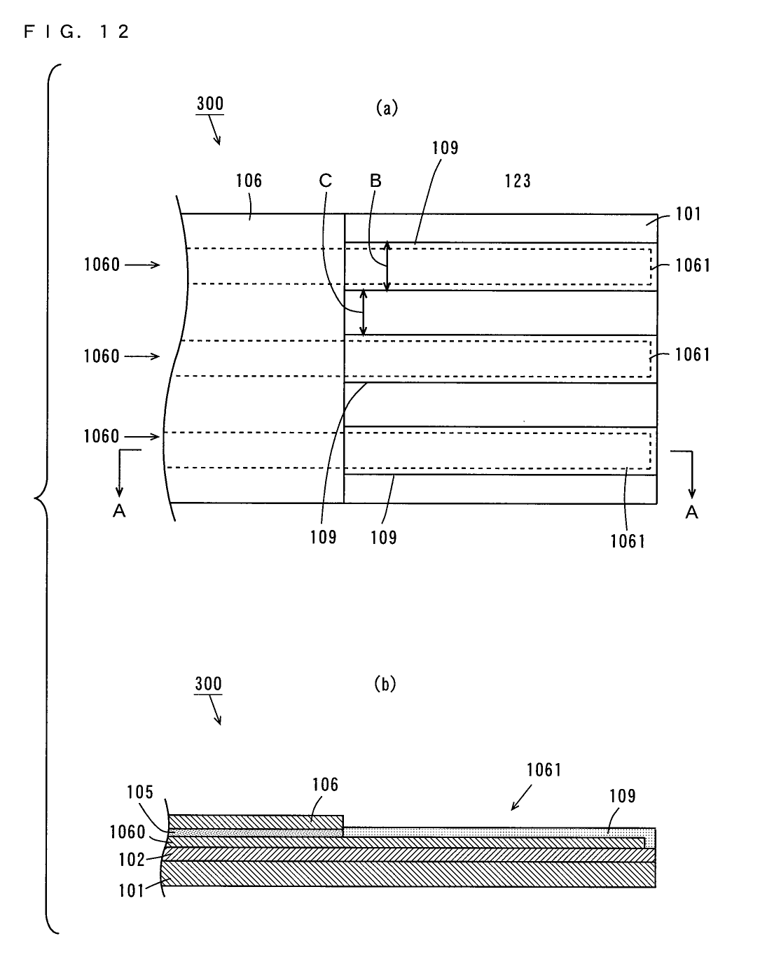

FIG. 12 shows the printed circuit board of the comparative example. Note that in FIG. 12, (a) is a top view, and (b) is a sectional view taken along the line A-A of (a).

The printed circuit board of the comparative example is different from the printed circuit board 100 of the inventive example 1 in the following points.

As shown in FIG. 12, the metal foil 102 was provided only on the upper surface of the base insulating layer 101 in the printed circuit board 300 of the comparative example. A plurality of long-sized wirings 1060 were formed on the metal foil 102. The wirings 1060 were formed by the same method as that used for forming the terminal portions 1041 of FIG. 4.

The cover insulating layer 106 was provided on the upper surface of the metal foil 102 with the adhesive layer 105 sandwiched therebetween such that terminal portions 1061 of the wirings 1060 were exposed. In addition, the protective plating layers 109 were provided in regions, which were not covered with the cover insulating layer 106, of the upper surface of the metal foil 102 so as to cover the wirings 1060. Note that the width B of each of the protective plating layer 109 was 150 μm, and the interval C between the adjacent protective plating layers 109 was 50 μm.

### (4) Evaluation

In the reliability tests, the printed circuit board 100 of the inventive example 1, the printed circuit board 200 of the inventive example 2 and the printed circuit board 300 of the comparative example were left for 12 hours in an atmosphere at a temperature of 65° C. and a humidity of 95%, and then a direct-current voltage of 50 V was each applied between the adjacent wirings 1040, between the adjacent wirings 1050 and between the adjacent wirings 1060. Then, respective resistance values between the adjacent wirings 1040, between the adjacent wirings 1050 and between the adjacent wirings 1060 were measured.

As a result, although the resistance value between the wirings 1060 became 1×10⁶ [Ω] or less after 380 hours in the printed circuit board 300 of the comparative example, the resistance values between the wirings 1040 and between the wirings 1050 did not become 1×10⁶ [Ω] or less even after 1000 hours in the printed circuit board 100 of the inventive example 1 and the printed circuit board 200 of the inventive example 2.

Here, the boundaries between the protective plating layers 109 and the cover insulating layer 106 were positioned above the wirings 1060 in the printed circuit board 300 of the comparative example (FIG. 12). Therefore, a distance between the foregoing boundary of one wiring 1060 and the foregoing boundary of another wiring 1060 adjacent thereto was short in the printed circuit board 300 of the comparative example. Thus, when copper ions of the one wiring 1060 were eluted from the foregoing boundary, the copper ions were liable to easily reach the foregoing boundary of the other wiring 1060 adjacent to the one wiring 1060. As a result, it is considered that the resistance value between the wirings 1060 of the printed circuit board 300 of the comparative example rapidly decreased as compared to the resistance value between the wirings 1040 of the inventive example 1 and the resistance value between the wirings 1050 of the inventive example 2.

Meanwhile, the boundaries between the protective plating layers 109 and the cover insulating layer 108 were inside the through holes 123 in the printed circuit boards 100, 200 of the inventive example 1 and the inventive example 2 (FIGS. 6 and 11). Therefore, even when copper ions were eluted from the terminal portions 1041, the wiring patterns 1042 or the wiring patterns 1044, the copper ions could be prevented from reaching other terminal portions 1041, wiring patterns 1042 or wiring patterns 1044 through the foregoing boundaries. As a result, it is considered that insulating reliability of the printed circuit boards 100, 200 of the inventive examples 1 and 2 were improved.

What is claimed is:

1. A printed circuit board comprising:
a base insulating layer including a first through hole;
a terminal portion that is made of a metal material and provided on a region, including said first through hole, of one surface of said base insulating layer;
a first conductor pattern provided on a region, including said first through hole, of the other surface of said base insulating layer;
a first metal layer that electrically connects said terminal portion and said first conductor pattern through said first through hole;
a protective layer that is made of a metal material and provided on the side of said one surface of said base insulating layer so as to cover said terminal portion and said first metal layer; and
a first insulating cover layer that is provided on said other surface of said base insulating layer so as to cover said first conductor pattern and said first through hole.

2. The printed circuit board according to claim 1, wherein the metal material for said protective layer includes at least one of nickel, gold and solder.

3. The printed circuit board according to claim 1, wherein said first metal layer is provided along an inner wall surface of said first through hole, and said protective layer is provided in said first through hole so as to cover a surface of said first metal layer.

4. The printed circuit board according to claim 1, wherein said base insulating layer further includes a second through hole, and said first conductor pattern is provided on a region, including said first and second through holes, of said other surface of said base insulating layer,
said printed circuit board further comprising:
a second conductor pattern provided on a region, including said second through hole, of said one surface of said base insulating layer;
a second metal layer that connects said first conductor pattern and said second conductor pattern through said second through hole; and
a second insulating cover layer provided on said one surface of said base insulating layer so as to cover said second conductor pattern and said second through hole.
